(19) United States
(12) Patent Application Publication
(10) Pub. No.: US 2022/0310617 A1
(43) Pub. Date: Sep. 29, 2022

(54) SEMICONDUCTOR DEVICE AND MANUFACTURING METHOD THEREOF

(71) Applicant: CHANGXIN MEMORY TECHNOLOGIES, INC., Hefei City, Anhui Province (CN)

(72) Inventor: Tong WU, Hefei City (CN)

(73) Assignee: CHANGXIN MEMORY TECHNOLOGIES, INC., Hefei City, Anhui Province (CN)

(21) Appl. No.: 17/601,584

(22) PCT Filed: May 31, 2021
(86) PCT No.: PCT/CN2021/097500

§ 371 Date: Oct. 5, 2021

(30) Foreign Application Priority Data
Sep. 2, 2020 (CN) 202010907787.5

(51) Int. Cl. H01L 27/108

(52) U.S. Cl. CPC H01L 27/10808; H01L 27/1085

(57) ABSTRACT

The present disclosure provides a semiconductor device and a manufacturing method thereof, and relates to the field of semiconductor technologies. A manufacturing method includes: providing a substrate; forming a metal wiring layer on the substrate; etching the metal wiring layer to form a plurality of spaced metal interconnection structures; forming a first dielectric layer on a side wall of each metal interconnection structure and a surface of the metal interconnection structure away from the substrate; and depositing a second dielectric layer in a gap between the metal interconnection structures, the second dielectric layer covering the first dielectric layer, and the first dielectric layer and the second dielectric layer being both made of materials with low dielectric constants. The manufacturing method according to the present disclosure may reduce a parasitic capacitance and power consumption of the device, and improve a product stability.

### CROSS-REFERENCE TO RELATED APPLICATIONS

This application is a national phase entry of International Patent Application No. PCT/CN2021/097500 filed on May 31, 2021, which claims priority to Chinese Patent Application No. 202010907787.5, filed on Sep. 2, 2020. The entire contents of the aforementioned patent applications are incorporated herein by reference.

### TECHNICAL FIELD

The present disclosure relates to the field of semiconductor technologies, in particular to a semiconductor device and a manufacturing method thereof.

### BACKGROUND

With a continuous development of mobile devices, battery-powered mobile devices, such as mobile phones, tablet computers, wearable devices, or the like, are increasingly applied to life, and people have great demands on miniaturization and integration of memories as essential elements in the mobile devices.

Currently, a dynamic random access memory (DRAM) is widely applied to the mobile device due to a high transmission speed. However, with a continuous reduction of a size of a semiconductor device, more and more leads are provided per unit area, such that a spacing between the leads becomes smaller, and a parasitic capacitance between the leads is increased in a high frequency state, thus increasing power consumption of the semiconductor device.

It is to be noted that the above information disclosed in this Background section is only for enhancement of understanding of the background of the present disclosure and therefore it may contain information that does not form the prior art that is already known to a person of ordinary skill in the art.

### SUMMARY

According to an aspect of the present disclosure, there is provided a manufacturing method of a semiconductor device, including:

providing a substrate;

forming a metal wiring layer on the substrate;

etching the metal wiring layer to form a plurality of spaced metal interconnection structures;

forming a first dielectric layer on a side wall of each metal interconnection structure and a surface of the metal interconnection structure away from the substrate; and

depositing a second dielectric layer in a gap between the metal interconnection structures, the second dielectric layer covering the first dielectric layer, and the first dielectric layer and the second dielectric layer being both made of materials with low dielectric constants.

According to an aspect of the present disclosure, there is provided a semiconductor device, including:

a substrate;

a metal wiring layer formed on the substrate and including a plurality of spaced metal interconnection structures;

a first dielectric layer formed on a side wall of each metal interconnection structure and a surface of the metal interconnection structure away from the substrate; and

a second dielectric layer covering the first dielectric layer, the second dielectric layer being deposited in a gap between the metal interconnection structures, and the first dielectric layer and the second dielectric layer being both made of materials with low dielectric constants.

### BRIEF DESCRIPTION OF DRAWINGS

The accompanying drawings herein are incorporated in and constitute a part of this specification, illustrate embodiments conforming to the present disclosure and, together with the description, serve to explain the principles of the present disclosure. Apparently, the accompanying drawings in the following description show merely some embodiments of the present disclosure, and persons of ordinary skill in the art may still derive other drawings from these accompanying drawings without creative efforts.

FIG. 1 is a schematic structural diagram of a semiconductor device in a related art.

FIG. 2 is a flow chart of a manufacturing method of a semiconductor device according to an embodiment of the present disclosure.

FIG. 3 is a schematic diagram of a metal wiring layer according to an embodiment of the present disclosure.

FIG. 4 is a schematic diagram of a metal interconnection structure according to an embodiment of the present disclosure.

FIG. 5 is a schematic diagram of a first dielectric layer according to an embodiment of the present disclosure.

FIG. 6 is a schematic diagram of a second dielectric layer according to an embodiment of the present disclosure.

FIG. 7 is a schematic diagram of an air gap according to an embodiment of the present disclosure.

FIG. 8 is a schematic diagram of a semiconductor device according to an embodiment of the present disclosure.

In the drawings: 100: substrate; 200: metal interconnection structure; 300: silicon oxide layer; 301: air gap; 1: substrate; 11: electric conductor; 2: metal wiring layer; 21: metal interconnection structure; 3: first dielectric layer; 4: second dielectric layer; 41: air gap; 5: protective layer; 6: barrier layer.

### DESCRIPTION OF EMBODIMENTS

The exemplary embodiment will now be described more fully with reference to the accompanying drawings. However, the exemplary embodiments may be implemented in a variety of forms and should not be construed as limited to the embodiments set forth herein. Rather, the embodiments are provided such that the present invention will be thorough and complete and will fully convey the concepts of exemplary embodiments to those skilled in the art. Throughout the drawings, similar reference signs indicate the same or similar structures, and their detailed description will be omitted.

The features, structures, or characteristics described above can be combined in one or more embodiments in any suitable manner. If possible, the features discussed in the embodiments are interchangeable. In the above description, numerous specific details are provided in order to give a thorough understanding of the embodiments of the present invention. Those skilled in the art will recognize, however, that the technical solutions of the present invention may be practiced without one or more of the specific details, or with other methods, materials, or the like. In other instances, well known structures, materials, or operations are not shown or described in detail to avoid obscuring aspects of the present invention.

Although relative terms such as “above” and “below” are used herein to describe a relative relation between one component and another component of icons, these terms are merely for convenience of this specification, for example, the directions of the examples in the accompanying drawings. It is to be understood that when the apparatus of the icon is turned upside down, components described as “above” will become components described as “below”. When a certain structure is “above” other structures, it likely means that a certain structure is integrally formed on other structures, or a certain structure is “directly” arranged on other structures, or a certain structure is “indirectly” arranged on other structures by means of another structure.

The terms “one”, “a”, “the” and “at least one” are intended to mean that there exists one or more elements/constituent parts/etc. The terms “comprising” and “having” are intended to be inclusive and mean that there may be additional elements/constituent parts/etc. other than the listed elements/constituent parts/etc. The terms “first” and “second” are used merely as labels, not to limit the number of their objects.

In a related art, as shown in FIG. 1, a semiconductor device mainly includes a substrate 100, a metal interconnection structure 200, and a silicon oxide layer 300 provided on a periphery of the metal interconnection structure 200, wherein the metal interconnection structure 200 is located on the substrate 100, and the silicon oxide layer 300 is filled between the metal interconnection structures 200 and may support each metal interconnection structure 200, so as to guarantee a stability of the device. An air gap 301 structure may be provided in the silicon oxide layer 300, so as to reduce a parasitic capacitance between the metal interconnection structures 200. However, due to limitations of materials and processes, the formed air gap 301 has a top surface usually higher than a top surface of the metal interconnection structure 200, such that a crack is prone to generation between metal interconnection wires in subsequent packaging and practical applications, thus affecting the stability of the device.

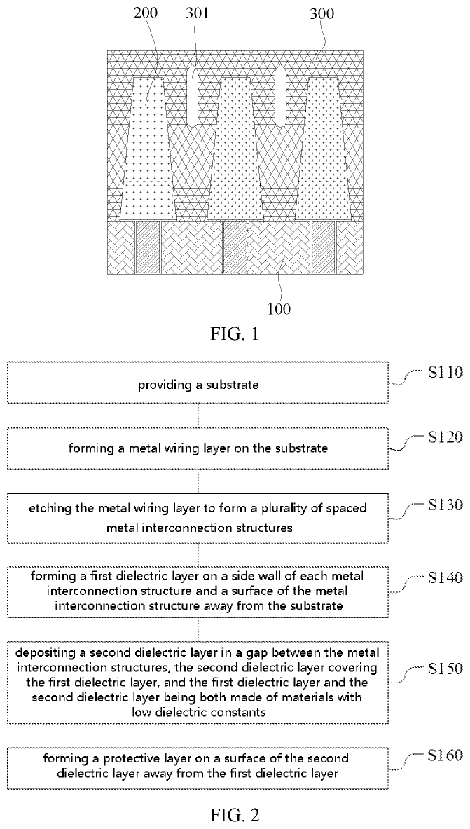

An embodiment of the present disclosure provides a manufacturing method of a semiconductor device, as shown in FIG. 2, including:
S110: providing a substrate;
S120: forming a metal wiring layer on the substrate;
S130: etching the metal wiring layer to form a plurality of spaced metal interconnection structures;
S140: forming a first dielectric layer on a side wall of each metal interconnection structure and a surface of the metal interconnection structure away from the substrate; and
S150: depositing a second dielectric layer in a gap between the metal interconnection structures, the second dielectric layer covering the first dielectric layer, and the first dielectric layer and the second dielectric layer being both made of materials with low dielectric constants.

In the manufacturing method of a semiconductor device according to the present disclosure, on the one hand, the first dielectric layer with the low dielectric constant is provided between the metal interconnection structures, thus effectively reducing the parasitic capacitance between the metal interconnection structures to reduce power consumption of the device; on the other hand, the second dielectric layer with the lower dielectric constant is deposited on a surface of the first dielectric layer, and the first dielectric layer and the second dielectric layer function simultaneously to further reduce the parasitic capacitance and thus the power consumption of the device; meanwhile, since the gap between the metal interconnection structures is filled with the second dielectric layer, metal interconnection wires may be transversely supported by the second dielectric layer, thereby improving a product stability.

Steps of the manufacturing method of a semiconductor device according to an embodiment of the present disclosure will be described below in detail.

S110: providing the substrate.

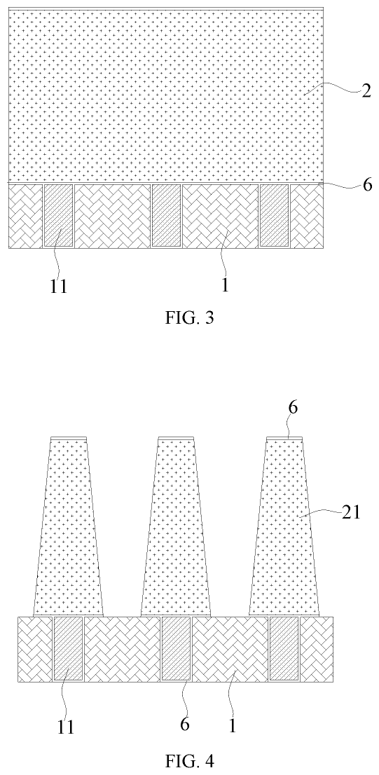

As shown in FIGS. 3 to 8, the substrate 1 may have a flat plate structure, have a rectangular, circular, oval, polygonal, or irregular shape, and be made of silicon or other semiconductor materials, and the shape and material of the substrate 1 are not particularly limited herein.

The substrate 1 may be formed therein with a plurality of spaced electric conductors 11, and an upper structure and a lower structure of the substrate 1 may be connected by the electric conductor 11. In an embodiment, the electric conductor 11 may be made of a conductor or semiconductor material, for example, tungsten, copper, or the like. Specifically, a via may be formed in the substrate 1 using a photolithography process, be configured as a through hole, and have a cross section in a circular, rectangular, or irregular shape, which is not particularly limited herein. The electric conductor 11 may be formed within the via by means of chemical vapor deposition, vacuum evaporation, or the like.

S120: forming the metal wiring layer on the substrate.

The metal wiring layer 2 may be formed on the surface of the substrate 1 using chemical vapor deposition, vacuum evaporation, magnetron sputtering, atomic layer deposition or other means, and as shown in FIG. 3, the metal wiring layer 2 may cover and be connected with each electric conductor 11 through contact. The metal wiring layer 2 may be configured as a thin film or a coating formed on the substrate 1, and be made of a metal material, for example, aluminum, copper or other materials capable of serving as a lead, which is not particularly limited herein.

S130: etching the metal wiring layer to form the plurality of spaced metal interconnection structures.

As shown in FIG. 4, the metal wiring layer 2 may be anisotropically etched to form the plurality of spaced metal interconnection structures 21, a number of the metal interconnection structures 21 may be the same as that of the electric conductors 11, and the metal interconnection structures may be connected with the electric conductors 11 in one-to-one correspondence. In an embodiment of the present disclosure, the metal interconnection structure 21 may be configured as an outermost metal interconnection structure 21 formed in a back-segment-wire interconnection structure, and be connected with the metal interconnection structures of other layers by the electric conductors 11.

In an embodiment, as shown in FIG. 4, a barrier layer 6 may further be formed on the surface of the metal interconnection structure 21 and attached thereto to prevent the metal material from diffusing into an adjacent film, and meanwhile, the barrier layer 6 may also have an adhesion function for improving adhesion between the metal interconnection structure 21 and the film adjacent thereto. The barrier layer 6 may have a single-layer film structure or a multi-layer film structure, and be made of a conductive material, such as tantalum, titanium, tantalum nitride, titanium nitride, or other materials, which is not particularly limited herein.

S140: forming the first dielectric layer on the side wall of each metal interconnection structure and the surface of the metal interconnection structure away from the substrate.

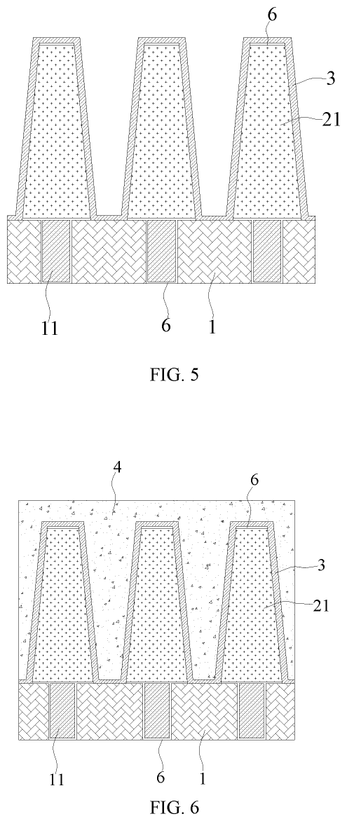

As shown in FIG. 5, the first dielectric layer 3 may be formed on the side wall of the metal interconnection structure 21 and the surface of the metal interconnection structure 21 away from the substrate 1 by means of chemical vapor deposition, physical vapor deposition, magnetron sputtering, or the like, and meanwhile, the first dielectric layer 3 may also be formed on a surface of the substrate 1 not covered with the metal interconnection structure 21. The first dielectric layer 3 may be configured as a thin film formed on the surfaces of the metal interconnection structure 21 and the substrate 1, be conformally attached to a surface of a structure formed by the metal interconnection structure 21 and the substrate 1, and have a thickness ranging from 0 nm to 100 nm, for example, 0 nm, 20 nm, 40 nm, 60 nm, 80 nm, 100 nm, or other thicknesses, which are not listed herein.

The first dielectric layer 3 may be made of a material with a low dielectric constant, so as to reduce the parasitic capacitance between the metal interconnection structures 21. For example, the first dielectric layer 3 may be configured as a carbon-doped silicon oxide layer, or a fluorine-doped silicon oxide layer, or made of other materials with a low dielectric constant, which are not listed herein.

In a first embodiment of the present disclosure, the first dielectric layer 3 may be made of carbon-doped silicon oxide, the carbon-doped silicon oxide layer may be formed on the side wall of the metal interconnection structure 21 and the surface of the metal interconnection structure 21 away from the substrate 1 by means of chemical vapor deposition using a silicon-containing material, carbon-containing gas and oxygen, and a doping concentration of carbon ions in the carbon-doped silicon oxide layer may be greater than 0 and less than or equal to 20%. Tetraethoxysilane may be used as the silicon-containing material, and the carbon-containing gas may be acetylene, propylene or other carbon-containing gas, which is not particularly limited herein.

In a second embodiment of the present disclosure, the first dielectric layer 3 may be made of fluorine-doped silicon oxide, the fluorine-doped silicon oxide layer may be formed on the side wall of the metal interconnection structure 21 and the surface of the metal interconnection structure 21 away from the substrate 1 by means of chemical vapor deposition using a silicon-containing material, fluorine-containing gas and oxygen, and a doping concentration of fluorine ions in the fluorine-doped silicon oxide layer may be greater than 0 and less than or equal to 20%. Silane may be used as the silicon-containing material, and the fluorine-containing gas may be carbon tetrafluoride, nitrogen trifluoride, sulfur hexafluoride, or other fluorine-containing gas, which is not particularly limited herein.

S150: depositing the second dielectric layer in the gap between the metal interconnection structures, the second dielectric layer covering the first dielectric layer, and the first dielectric layer and the second dielectric layer being both made of the materials with low dielectric constants.

As shown in FIG. 6, the second dielectric layer 4 covering the first dielectric layer 3 may be formed by means of chemical vapor deposition, physical vapor deposition, magnetron sputtering, or the like. The second dielectric layer 4 may be configured as a thin film formed on the surface of the first dielectric layer 3, and be made of a material with a low dielectric constant, and the first dielectric layer 3 and the second dielectric layer 4 function simultaneously to further reduce the parasitic capacitance and thus the power consumption of the device. For example, the second dielectric layer 4 may be made of a material different from the first dielectric layer 3, configured as a fluorine-doped silicon oxide layer, or a carbon-doped silicon oxide layer, or made of other materials with a low dielectric constant, which are not listed herein.

The gaps between the metal interconnection structures 21 may be filled or filled up with the second dielectric layer 4, and the surface of the second dielectric layer 4 away from the substrate 1 may be higher than the surface of the metal interconnection structure 21 away from the substrate 1, and be configured as a flat plane; in an embodiment, the second dielectric layer 4 may have a thickness ranging from 500 nm to 1200 nm, for example, 500 nm, 700 nm, 900 nm, 1100 nm, 1200 nm, or other thicknesses, which are not listed herein. Each metal interconnection wire may be transversely supported by the second dielectric layer 4, thereby improving the product stability.

In a first embodiment of the present disclosure, the first dielectric layer 3 may be made of carbon-doped silicon oxide, the second dielectric layer 4 may be made of fluorine-doped silicon oxide, the fluorine-doped silicon oxide layer (i.e., a fluorine-containing silicon oxide layer) may be formed on the surface of the carbon-doped silicon oxide layer with a high-density plasma chemical deposition process using a silicon-containing material, fluorine-containing gas and oxygen, and a doping concentration of fluorine ions in the fluorine-doped silicon oxide layer may be greater than 0 and less than or equal to 20%. The fluorine-containing gas may be carbon tetrafluoride, nitrogen trifluoride, sulfur hexafluoride, or other fluorine-containing gas, which is not particularly limited herein.

For example, a deposition ratio of the fluorine-containing gas to the oxygen may be controlled to form a dense fluorine-containing silicon oxide layer on the surface of the carbon-doped silicon oxide layer, so as to improve the stability of the device. For example, the deposition ratio of the fluorine-containing gas to the oxygen during material deposition may be 2.0-3.0, such as 2.0, 2.2, 2.4, 2.6, 2.8, 3.0, or other deposition ratios, which are not listed herein.

In a second embodiment of the present disclosure, the first dielectric layer 3 may be made of fluorine-doped silicon oxide, the second dielectric layer 4 may be made of carbon-doped silicon oxide, the carbon-doped silicon oxide layer (i.e., a carbon-containing silicon oxide layer) may be formed on the surface of the fluorine-doped silicon oxide layer with a high-density plasma chemical deposition process using a silicon-containing material, carbon-containing gas and oxygen, and a doping concentration of carbon ions in the carbon-doped silicon oxide layer may be greater than 0 and less than or equal to 20%. Tetraethoxysilane may be used as the silicon-containing material, and the carbon-containing gas may beacetylene, propylene or other carbon-containing gas, which is not particularly limited herein.

For example, a deposition ratio of the carbon-containing gas to the oxygen may be controlled to form a dense carbon-containing silicon oxide layer on the surface of the fluorine-doped silicon oxide layer, so as to improve the stability of the device. For example, the deposition ratio of the carbon-containing gas to the oxygen during material deposition may be 2.0-3.0, such as 2.0, 2.2, 2.4, 2.6, 2.8, 3.0, or other deposition ratios, which are not listed herein.

In an embodiment of the present disclosure, S150 may include: controlling a deposition rate of the second dielectric layer 4 to form an air gap 41 in the gap between the metal interconnection structures 21, the air gap 41 having a top surface not beyond a top surface of the metal interconnection structure 21.

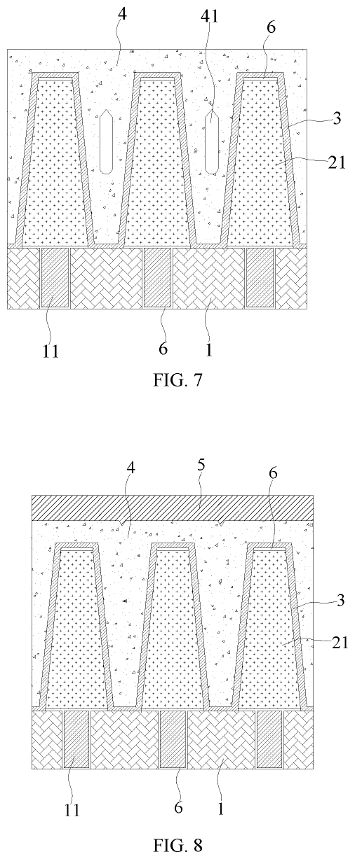

As shown in FIG. 7, the air gap 41 may be formed in the gap between the metal interconnection structures 21, and air has a dielectric constant much less than that of silicon oxide, thereby further reducing the parasitic capacitance between the metal interconnection wires. The top surface of the air gap 41 is not beyond the top surface of the metal interconnection structure 21, thereby preventing a crack from being generated between the metal interconnection wires in subsequent packaging and practical applications, so as to guarantee the stability of the device.

In an embodiment, the first dielectric layer 3 is made of carbon-doped silicon oxide, the second dielectric layer 4 is made of fluorine-doped silicon oxide, and during formation of the second dielectric layer 4, the air gap 41 may be formed in the gap between the metal interconnection structures 21 by controlling the deposition ratio of fluorine-containing gas to oxygen, and in this process, a sealing height of the air gap 41 may be adjusted by adjusting the deposition rate of the silicon oxide layer and an etching ratio of the fluorine-containing gas, such that the top surface of the air gap 41 is not beyond the top surface of the metal interconnection structure 21. For example, the deposition ratio of the fluorine-containing gas to the oxygen may be 7.0-8.0 during the formation of the air gap 41, and 2.0-3.0 in the sealing process.

In another embodiment, the first dielectric layer 3 is made of fluorine-doped silicon oxide, the second dielectric layer 4 is made of carbon-doped silicon oxide, and during formation of the second dielectric layer 4, the air gap 41 may be formed in the gap between the metal interconnection structures 21 by controlling the deposition ratio of carbon-containing gas to oxygen, and in this process, the sealing height of the air gap 41 may be adjusted by adjusting the deposition rate of the silicon oxide layer and an etching ratio of the carbon-containing gas, such that the top surface of the air gap 41 is not beyond the top surface of the metal interconnection structure 21. For example, the deposition ratio of the carbon-containing gas to the oxygen may be 7.0-8.0 during the formation of the air gap 41, and 2.0-3.0 in the sealing process.

In an embodiment, the manufacturing method according to the present disclosure may further include:

5160: forming a protective layer on the surface of the second dielectric layer away from the first dielectric layer.

As shown in FIG. 8, the protective layer 5 may cover the surface of the second dielectric layer 4 away from the first dielectric layer 3, and be configured to protect the second dielectric layer 4. The protective layer 5 may be formed on the surface of the second dielectric layer 4 away from the first dielectric layer 3 by means of chemical vapor deposition, physical vapor deposition, magnetron sputtering, or the like.

The protective layer 5 may have a single-layer or multi-layer structure, and be made of an insulating material, specifically, silicon nitride, silicon oxide, or other insulating materials, which are not listed herein.

An embodiment of the present disclosure may further provide a semiconductor device, as shown in FIG. 8, including a substrate 1, a metal wiring layer 2, a first dielectric layer 3 and a second dielectric layer 4.

The metal wiring layer 2 is formed on the substrate 1 and includes a plurality of spaced metal interconnection structures 21.

The first dielectric layer 3 is formed on a side wall of each metal interconnection structure 21 and a surface of the metal interconnection structure away from the substrate 1.

The second dielectric layer 4 covers the first dielectric layer 3, and is deposited in a gap between the metal interconnection structures 21, and the first dielectric layer 3 and the second dielectric layer 4 are both made of materials with low dielectric constants.

In the semiconductor device according to the present disclosure, on the one hand, the first dielectric layer 3 with the low dielectric constant is provided between the metal interconnection structures 21, thus effectively reducing a parasitic capacitance between the metal interconnection structures 21 to reduce power consumption of the device; on the other hand, the second dielectric layer 4 with the lower dielectric constant is deposited on the surface of the first dielectric layer 3, and the first dielectric layer 3 and the second dielectric layer 4 function simultaneously to further reduce the parasitic capacitance and thus the power consumption of the device; meanwhile, since the gap between the metal interconnection structures 21 is filled with the second dielectric layer 4, metal interconnection wires may be transversely supported by the second dielectric layer 4, thereby improving a product stability.

As shown in FIG. 3, the substrate 1 may have a flat plate structure, have a rectangular, circular, oval, polygonal, or irregular shape, and be made of silicon or other semiconductor materials, and the shape and material of the substrate 1 are not particularly limited herein.

The substrate 1 may be formed therein with a plurality of spaced electric conductors 11, and an upper structure and a lower structure of the substrate 1 may be connected by the electric conductor 11. In an embodiment, the electric conductor 11 may be made of a conductor or semiconductor material, for example, tungsten, copper, or the like. Specifically, a via may be formed in the substrate 1 using a photolithography process, be configured as a through hole, and have a cross section in a circular, rectangular, or irregular shape, which is not particularly limited herein. The electric conductor 11 may be formed within the via by means of chemical vapor deposition, vacuum evaporation, or the like.

The metal wiring layer 2 may be formed on the surface of the substrate 1 using chemical vapor deposition, vacuum evaporation, magnetron sputtering, atomic layer deposition or other means, and the metal wiring layer 2 may cover and be connected with each electric conductor 11 through contact. The metal wiring layer 2 may be configured as a thin film or a coating formed on the substrate 1, and be made of a metal material, for example, aluminum, copper or other materials capable of serving as a lead, which is not particularly limited herein.

As shown in FIG. 4, the metal wiring layer 2 may be anisotropically etched to form the plurality of spaced metal interconnection structures 21, a number of the metal interconnection structures 21 may be the same as that of the electric conductors 11, and the metal interconnection structures may be connected with the electric conductors 11 in one-to-one correspondence. In an embodiment of the present disclosure, the metal interconnection structure 21 may be configured as an outermost metal interconnection structure 21 formed in a back-segment-wire interconnection structure, and be connected with the metal interconnection structures of other layers by the electric conductors 11.

In an embodiment, as shown in FIG. 4, a barrier layer 6 may further be formed on the surface of the metal interconnection structure 21 and attached thereto to prevent the metal material from diffusing into an adjacent film, and meanwhile, the barrier layer 6 may also have an adhesion function for improving adhesion between the metal interconnection structure 21 and the film adjacent thereto. The barrier layer 6 may have a single-layer film structure or a multi-layer film structure, and be made of a conductive material, such as tantalum, titanium, tantalum nitride, titanium nitride, or other materials, which is not particularly limited herein.

As shown in FIG. 5, the first dielectric layer 3 may be formed on the side wall of the metal interconnection structure 21 and the surface of the metal interconnection structure 21 away from the substrate 1 by means of chemical vapor deposition, physical vapor deposition, magnetron sputtering, or the like, and meanwhile, the first dielectric layer 3 may also be formed on a surface of the substrate 1 not covered with the metal interconnection structure 21. The first dielectric layer 3 may be configured as a thin film formed on the surfaces of the metal interconnection structure 21 and the substrate 1, be conformally attached to a surface of a structure formed by the metal interconnection structure 21 and the substrate 1, and have a thickness ranging from 0 nm to 100 nm, for example, 0 nm, 20 nm, 40 nm, 60 nm, 80 nm, 100 nm, or other thicknesses, which are not listed herein.

The first dielectric layer 3 may be made of a material with a low dielectric constant, so as to reduce the parasitic capacitance between the metal interconnection structures 21. For example, the first dielectric layer 3 may be configured as a carbon-doped silicon oxide layer, or a fluorine-doped silicon oxide layer, or made of other materials with a low dielectric constant, which are not listed herein.

In a first embodiment of the present disclosure, the first dielectric layer 3 may be made of carbon-doped silicon oxide, the carbon-doped silicon oxide layer may be formed on the side wall of the metal interconnection structure 21 and the surface of the metal interconnection structure 21 away from the substrate 1 by means of chemical vapor deposition using a silicon-containing material, carbon-containing gas and oxygen, and a doping concentration of carbon ions in the carbon-doped silicon oxide layer may be greater than 0 and less than or equal to 20%. Tetraethoxysilane may be used as the silicon-containing material, and the carbon-containing gas may be acetylene, propylene or other carbon-containing gas, which is not particularly limited herein.

In a second embodiment of the present disclosure, the first dielectric layer 3 may be made of fluorine-doped silicon oxide, the fluorine-doped silicon oxide layer may be formed on the side wall of the metal interconnection structure 21 and the surface of the metal interconnection structure 21 away from the substrate 1 by means of chemical vapor deposition using a silicon-containing material, fluorine-containing gas and oxygen, and a doping concentration of fluorine ions in the fluorine-doped silicon oxide layer may be greater than 0 and less than or equal to 20%. Silane may be used as the silicon-containing material, and the fluorine-containing gas may be carbon tetrafluoride, nitrogen trifluoride, sulfur hexafluoride, or other fluorine-containing gas, which is not particularly limited herein.

As shown in FIG. 6, the second dielectric layer 4 covering the first dielectric layer 3 may be formed by means of chemical vapor deposition, physical vapor deposition, magnetron sputtering, or the like. The second dielectric layer 4 may be configured as a thin film formed on the surface of the first dielectric layer 3, and be made of a material with a low dielectric constant, and the first dielectric layer 3 and the second dielectric layer 4 function simultaneously to further reduce the parasitic capacitance and thus the power consumption of the device. For example, the second dielectric layer 4 may be made of a material different from the first dielectric layer 3, configured as a fluorine-doped silicon oxide layer, or a carbon-doped silicon oxide layer, or made of other materials with a low dielectric constant, which are not listed herein.

The gaps between the metal interconnection structures 21 may be filled or filled up with the second dielectric layer 4, and the surface of the second dielectric layer 4 away from the substrate 1 may be higher than the surface of the metal interconnection structure 21 away from the substrate 1, and be configured as a flat plane; in an embodiment, the second dielectric layer 4 may have a thickness ranging from 500 nm to 1200 nm, for example, 500 nm, 700 nm, 900 nm, 1100 nm, 1200 nm, or other thicknesses, which are not listed herein. Each metal interconnection wire may be transversely supported by the second dielectric layer 4, thereby improving the product stability.

In a first embodiment of the present disclosure, the first dielectric layer 3 may be made of carbon-doped silicon oxide, the second dielectric layer 4 may be made of fluorine-doped silicon oxide, the fluorine-doped silicon oxide layer (i.e., a fluorine-containing silicon oxide layer) may be formed on the surface of the carbon-doped silicon oxide layer with a high-density plasma chemical deposition process using a silicon-containing material, fluorine-containing gas and oxygen, and a doping concentration of fluorine ions in the fluorine-doped silicon oxide layer may be greater than 0 and less than or equal to 20%. The fluorine-containing gas may be carbon tetrafluoride, nitrogen trifluoride, sulfur hexafluoride, or other fluorine-containing gas, which is not particularly limited herein.

In a second embodiment of the present disclosure, the first dielectric layer 3 may be made of fluorine-doped silicon oxide, the second dielectric layer 4 may be made of carbon-doped silicon oxide, the carbon-doped silicon oxide layer (i.e., a carbon-containing silicon oxide layer) may be formed on the surface of the fluorine-doped silicon oxide layer with a high-density plasma chemical deposition process using a silicon-containing material, carbon-containing gas and oxygen, and a doping concentration of carbon ions in the carbon-doped silicon oxide layer may be greater than 0 and less than or equal to 20%. Tetraethoxysilane may be used as the silicon-containing material. The carbon-containing gas may be acetylene, propylene or other carbon-containing gas, which is not particularly limited herein.

As shown in FIG. 7, the air gap 41 may be formed in the gap between the metal interconnection structures 21, and air has a dielectric constant much less than that of silicon oxide, thereby further reducing the parasitic capacitance between the metal interconnection wires. The top surface of the air gap 41 is not beyond the top surface of the metal interconnection structure 21, thereby preventing a crack from being generated between the metal interconnection wires in subsequent packaging and practical applications, so as to guarantee the stability of the device.

As shown in FIG. 8, a protective layer 5 may cover a surface of the second dielectric layer 4 away from the first dielectric layer 3, and be configured to protect the second dielectric layer 4. The protective layer 5 may have a single-layer or multi-layer structure, and be made of an insulating material, specifically, silicon nitride, silicon oxide, or other insulating materials, which are not listed herein.

The semiconductor device may be configured as a memory chip, such as a DRAM, or other semiconductor devices, which are not listed herein.

Those skilled in the art will readily contemplate other embodiments of the present disclosure after considering the specification and practicing the invention. The present application is intended to cover any variations, uses, or adaptive changes of the present disclosure. These variations, uses, or adaptive changes follow the general principles of the present disclosure and include the common general knowledge or conventional technical means in this art which is not described herein. The specification and embodiments should be considered as exemplary only, and the true scope and spirit of the disclosure should be defined by the appended claims.

1. A manufacturing method of a semiconductor device, comprising:
providing a substrate;
forming a metal wiring layer on the substrate;
etching the metal wiring layer to form a plurality of spaced metal interconnection structures;
forming a first dielectric layer on a side wall of each metal interconnection structure and a surface of the metal interconnection structure away from the substrate; and
depositing a second dielectric layer in a gap between the metal interconnection structures, the second dielectric layer covering the first dielectric layer, and the first dielectric layer and the second dielectric layer being both made of materials with low dielectric constants.

2. The manufacturing method according to claim 1, wherein the forming a first dielectric layer on a side wall of each metal interconnection structure and a surface of the metal interconnection structure away from the substrate comprises:
forming a carbon-doped silicon oxide layer on the side wall of the metal interconnection structure and the surface away from the substrate by means of chemical vapor deposition using carbon-containing gas and oxygen;
or forming a fluorine-doped silicon oxide layer on the side wall of the metal interconnection structure and the surface away from the substrate by means of chemical vapor deposition using fluorine-containing gas and oxygen.

3. The manufacturing method according to claim 2, wherein the depositing a second dielectric layer in a gap between the metal interconnection structures, the second dielectric layer covering the first dielectric layer comprises:
forming a fluorine-containing silicon oxide layer on a surface of the carbon-doped silicon oxide layer with a high-density plasma chemical deposition process using fluorine-containing gas and oxygen;
or forming a carbon-containing silicon oxide layer on a surface of the fluorine-doped silicon oxide layer with a high-density plasma chemical deposition process using carbon-containing gas and oxygen.

4. The manufacturing method according to claim 1, wherein the depositing a second dielectric layer in a gap between the metal interconnection structures, the second dielectric layer covering the first dielectric layer comprises:
controlling a deposition rate of the second dielectric layer to form an air gap in the gap between the metal interconnection structures, the air gap having a top surface not beyond a top surface of the metal interconnection structure.

5. The manufacturing method according to claim 1, wherein the metal interconnection structure comprises an outermost metal interconnection structure formed in a back-segment-wire interconnection structure.

6. The manufacturing method according to claim 1, further comprising:
forming a protective layer on a surface of the second dielectric layer away from the first dielectric layer.

7. A semiconductor device, comprising:
a substrate;
a metal wiring layer formed on the substrate and comprising a plurality of spaced metal interconnection structures;
a first dielectric layer formed on a side wall of each metal interconnection structure and a surface of the metal interconnection structure away from the substrate; and
a second dielectric layer covering the first dielectric layer, the second dielectric layer being deposited in a gap between the metal interconnection structures, and the first dielectric layer and the second dielectric layer being both made of materials with low dielectric constants.

8. The semiconductor device according to claim 7, wherein the first dielectric layer is configured as a carbon-doped silicon oxide layer, and the second dielectric layer is configured as a fluorine-containing silicon oxide layer;
or the first dielectric layer is configured as a fluorine-doped silicon oxide layer, and the second dielectric layer is configured as a carbon-containing silicon oxide layer.

9. The semiconductor device according to claim 7, wherein an air gap is provided in the second dielectric layer located in the gap between the metal interconnection structures, and has a top surface not beyond a top surface of the metal interconnection structure.

10. The semiconductor device according to claim 7, further comprising:
a protective layer formed on a surface of the second dielectric layer away from the first dielectric layer.

11. The semiconductor device according to claim 8, further comprising:
a protective layer formed on a surface of the second dielectric layer away from the first dielectric layer.

12. The semiconductor device according to claim 9, further comprising:
a protective layer formed on a surface of the second dielectric layer away from the first dielectric layer.

13. The manufacturing method according to claim 2, further comprising:
forming a protective layer on a surface of the second dielectric layer away from the first dielectric layer.

14. The manufacturing method according to claim 3, further comprising:
forming a protective layer on a surface of the second dielectric layer away from the first dielectric layer.

15. The manufacturing method according to claim 4, further comprising:
forming a protective layer on a surface of the second dielectric layer away from the first dielectric layer.

16. The manufacturing method according to claim 5, further comprising:
forming a protective layer on a surface of the second dielectric layer away from the first dielectric layer.
